(19) United States
(12) Patent Application Publication
(10) Pub. No.: US 2012/0309164 A1
(43) Pub. Date: Dec. 6, 2012

(54) METHOD FOR MANUFACTURING SEMICONDUCTOR DEVICE

(75) Inventor: Narumi Ohkawa, Yokohama (JP)

(73) Assignee: FUJITSU SEMICONDUCTOR LIMITED, Yokohama-shi (JP)

(21) Appl. No.: 13/565,886

(22) Filed: Aug. 3, 2012

Related U.S. Application Data
(62) Division of application No. 12/885,004, filed on Sep. 17, 2010.
Application No. 12/885,004 is a continuation of application No. PCT/JP2008/056330, filed on Mar. 31, 2008.

(51) Int. Cl. H01L 21/02

(52) U.S. Cl. 438/396; 257/E21.008

(57) ABSTRACT

A method including forming an insulation layer over a semiconductor substrate; burying a first conduction layer containing Cu in the insulation layer in a first region and burying an interconnection containing Cu in the insulation layer in a second region; forming a barrier film of a conductive material; forming a dielectric film over the barrier metal film; forming a second conduction layer over the dielectric film; patterning the second conduction layer to form an upper electrode formed of the second conduction layer in the first region; and patterning the dielectric film and the barrier metal film to cover an upper surface of the first conduction layer by the first barrier film formed of the barrier metal film, form a lower electrode including the first conduction layer and the first barrier film, and covering an upper surface of the interconnection by the second barrier film formed of the barrier metal film.

### CROSS-REFERENCE TO RELATED APPLICATION

This application is a divisional application of U.S. application Ser. No. 12/885,004, filed on Sep. 17, 2010, which is a continuation of PCT application No. PCT/JP2008/056330, which was filed on Mar. 31, 2008, and which designated the United States of America, the entire contents of which are incorporated herein by reference.

### FIELD

The embodiments discussed herein are related to a semiconductor device and a method for manufacturing a semiconductor device.

BACKGROUND

For LSI, etc. including analog circuits, capacitance elements are important constituent members.

Conventionally, the capacitance elements have included polysilicon layers, impurity diffused layers, etc. as the electrodes. Recently, however, the capacitance element called an MIM (Metal-Insulator-Metal) capacitor is noted.

The MIM capacitor is a capacitance element comprising a capacitor insulation film sandwiched between a pair of electrodes of metal. The MIM capacitor can have the capacitive accuracy and the frequency characteristics improved, and is much noted.

On the other hand, recently, the use of Cu (copper) as a material of interconnections is noted so as to reduce the resistance of the interconnections.

To form the MIM capacitor of good frequency characteristics, it is preferable to set the electric resistance of the electrode low. If the lower electrode of the MIM capacitor can be formed concurrently with forming the interconnections, it could contribute to simplifying the manufacturing steps. To this end, the use of Cu is considered not only as a material of the interconnections but also as a material of the lower electrode of the MIM capacitor.

The lower electrode of Cu is buried in by forming a trench in an inter- layer insulation film, forming a Cu film in the trench and on the inter-layer insulation film and then polishing the Cu film until the surface of the inter-layer insulation film is exposed.

To form the MIM capacitor of a sufficient dielectric capacitance, it is necessary to set the opposed areas between the lower electrode and the upper electrode sufficiently large. To this end, the lower electrode of the MIM capacitor is buried in a trench formed in a large area.

Related references are as follows:

Japanese Laid-open Patent Publication No. 2001-237375,

Japanese Laid-open Patent Publication No. 2002-353221,

Japanese Laid-open Patent Publication No. 2005-311299, and

Japanese Laid-open Patent Publication No. 2005-150237.

### SUMMARY

According to an aspect of an embodiment, a semiconductor device including: an insulation layer formed over a semiconductor substrate; a capacitance element including a conduction layer containing Cu and formed in the insulation layer, a lower electrode including a first barrier film of a conductive material formed over the conduction layer and the insulation layer, a first dielectric film formed over the lower electrode, and an upper electrode formed over the first dielectric film; an interconnection containing Cu formed in the insulation layer; and a second barrier film of a conductive material formed over the interconnection and the insulation layer.

According to another aspect of the embodiment, a method for manufacturing a semiconductor device including a capacitance element having a lower electrode, a dielectric film formed over the lower electrode and an upper electrode formed over the dielectric film, said method including: forming an insulation layer over a semiconductor substrate; burying a first conduction layer containing Cu in the insulation layer in a first region and burying an interconnection containing Cu in the insulation layer in a second region; forming a barrier film of a conductive material over the first conduction layer, the interconnections and the insulation layer; forming a dielectric film over the barrier metal film; forming a second conduction layer over the dielectric film; patterning the second conduction layer to form an upper electrode formed of the second conduction layer in the first region; and patterning the dielectric film and the barrier metal film to cover an upper surface of the first conduction layer by the first barrier film formed of the barrier metal film, form a lower electrode including the first conduction layer and the first barrier film, and covering an upper surface of the interconnection by the second barrier film formed of the barrier metal film.

The object and advantages of the embodiments will be realized and attained by means of the elements and combinations particularly pointed out in the claims.

It is to be understood that both the foregoing general description and the following detailed description are exemplary and explanatory and are not restrictive of the embodiments, as claimed.

### BRIEF DESCRIPTION OF DRAWINGS

FIGS. 1A to 2B are cross-sectional views of the semiconductor device according to one embodiment;

FIGS. 3 and 4 are plan views of the semiconductor device according to the embodiment; and

FIGS. 5A to 24B are cross-sectional views of the semiconductor device according to the embodiment in the steps of the method for manufacturing the semiconductor device, which illustrate the method.

### DESCRIPTION OF EMBODIMENTS

In forming a trench in a large area and burying Cu film in such trench by CMP (Chemical Mechanical Polishing), a very deep dishing is formed in the surface of the Cu film. A technique of suppressing the dishing by forming a trench in a lattice and burying the Cu film in such trench is proposed. This technique, however, cannot surely provide good electric characteristics.

In the technique proposed in Patent Reference 1, a lower electrode is buried in an inter-layer insulation film, then silicon nitride film is formed on the inter-layer insulation film and the lower electrode, and then the silicon nitride film on the lower electrode is etched off.

In etching the silicon nitride film, the lower electrode is damaged, and the technique proposed in Patent Reference 1 cannot surely provide good electric characteristics.

Preferred embodiments of the present invention will be explained with reference to accompanying drawings.

### [a] One Embodiment

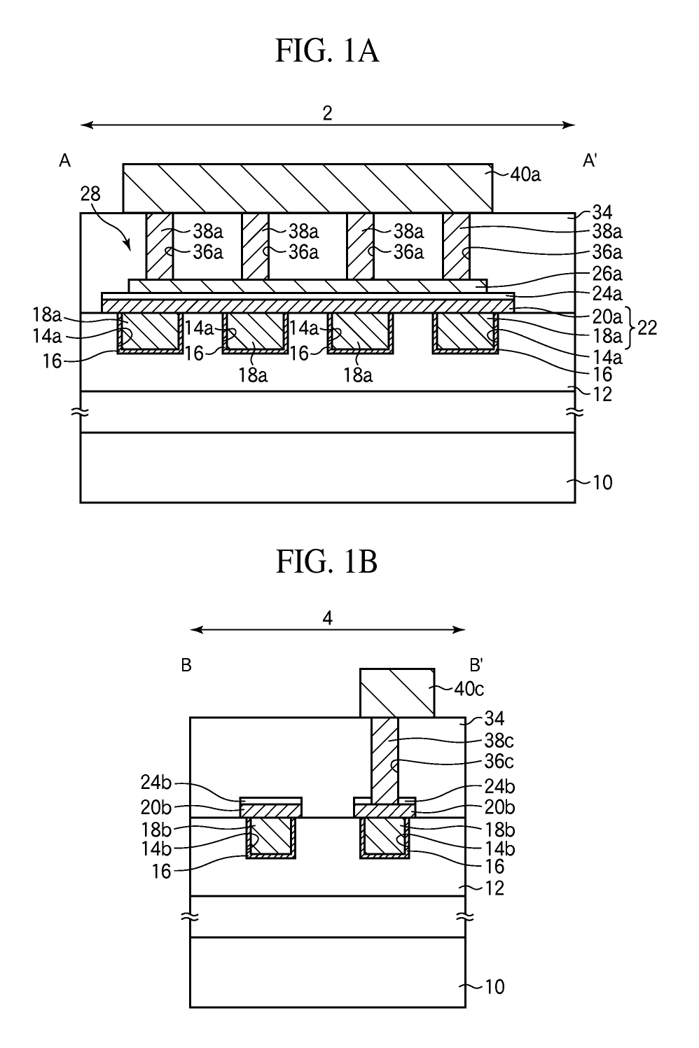

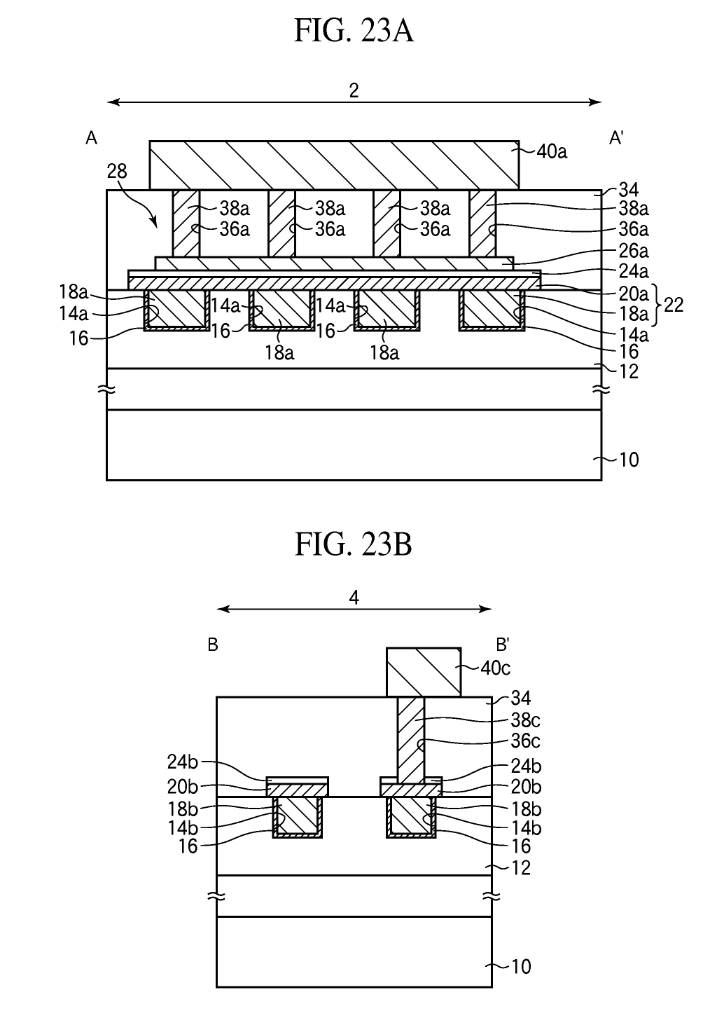

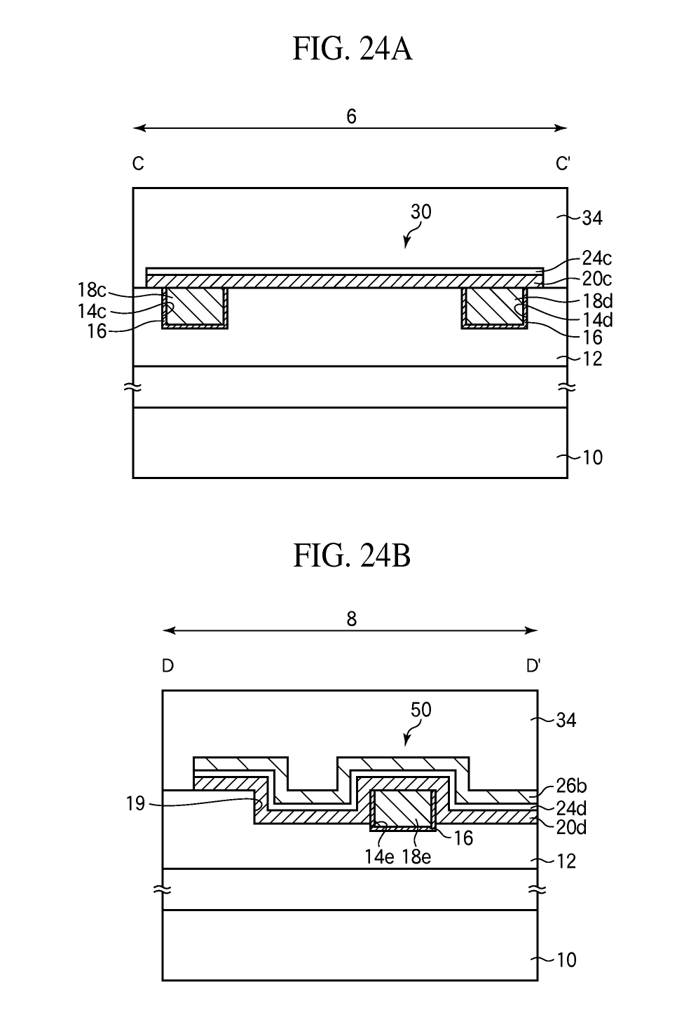

The semiconductor device according to one embodiment and its manufacturing method will be described with reference to FIGS. 1A to 24B.

(Semiconductor Device)

The semiconductor device according to the present embodiment will be described with reference to FIGS. 1A to 4B.

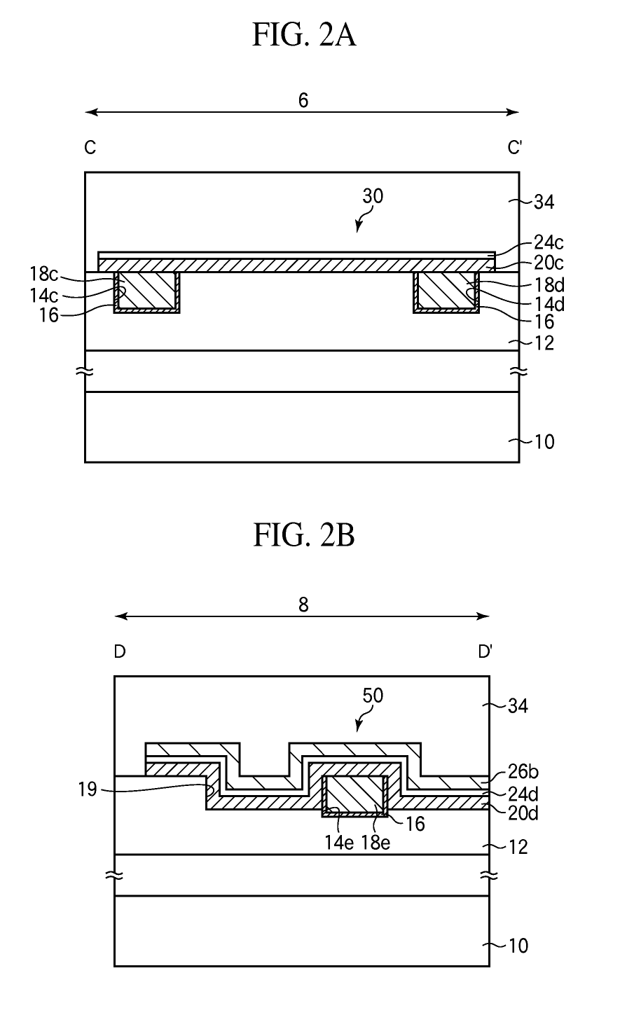

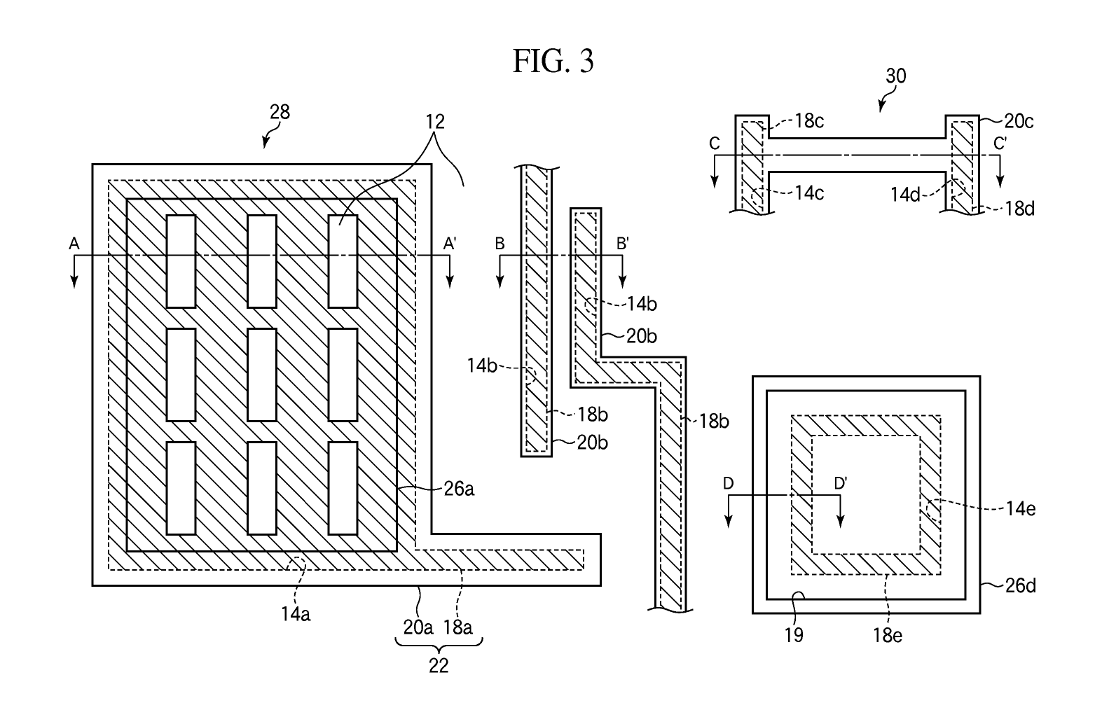

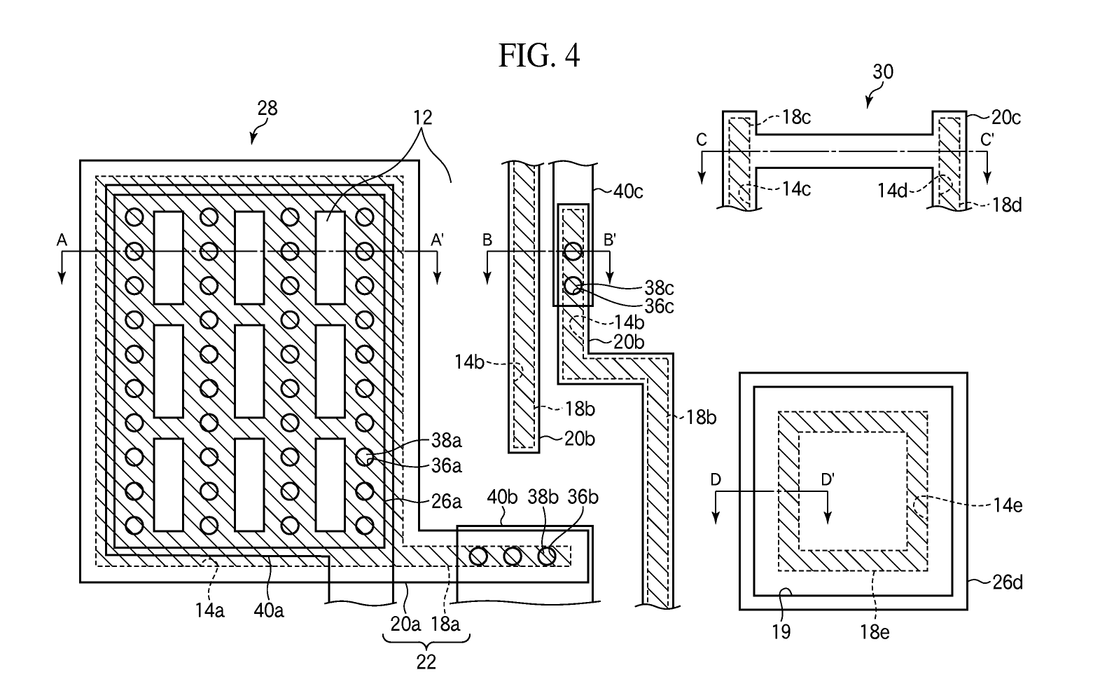

FIGS. 1A and 1B are cross-sectional views (Part 1) of the semiconductor device according to the present embodiment. FIGS. 2A and 2B are cross-sectional views (Part 2) of the semiconductor device according to the present embodiment. FIG. 3 is plan views (Part 1) of the semiconductor device according to the present embodiment. FIG. 4 is plan views (Part 2) of the semiconductor device according to the present embodiment.

FIG. 1A illustrates the cross-section of a region where a capacitance element (MIM capacitor) is formed. FIG 1A corresponds the cross-sections along the A-A′ line in FIG. 3 and the A-A′ line in FIG. 4. FIG. 1B illustrates the cross-section of a region where interconnections are formed. FIG. 1B corresponds to the cross-section along the B-B′ line in FIG. 3 and the cross-section along the B-B′ line in FIG. 4. FIG. 2A illustrates a region where a resistance element is formed. FIG. 2A corresponds to the cross-section along the C-C′ line in FIG. 3 and the cross-section along the C-C′ line in FIG. 4. FIG. 2B illustrates the cross-section of a region where an alignment mark is formed. FIG. 2B corresponds to the cross-section along the D-D′ line in FIG. 3 and the cross-section along the D-D′ line in FIG. 4.

On a semiconductor substrate 10, transistors, etc. not illustrated are formed. On the semiconductor substrate 10 with the transistors, etc. formed on, a multilayer interconnection structure (not illustrated) is formed.

First, the capacitance element 28 will be described.

As illustrated in FIG. 1A, in an inter-layer insulation film 12 in the region 2 where the capacitance element to be formed, trenches 14a for a conduction layer 18a buried in are formed. The trenches 14a are formed, enclosing parts of the inter-layer insulation film 12. The trenches 14a are formed, enclosing parts of the inter-layer insulation film 12 in the present embodiment so as not to generate a dishing in the surface of the conduction layer 18a.

In the trenches 14a, a barrier metal film 16 of a conductive material for preventing the diffusion of Cu is formed. The barrier metal film 16 is formed of, e.g., Ta film, TaN film or others.

In the trenches 14a with the barrier metal film 16 formed in, a conduction layer 18a of Cu are buried in. The conduction layer 18a is formed of Cu here. The conduction layer 18a form a part of a lower electrode 22 of the capacitance element 28.

The conduction layer 18a is formed of, e.g., Cu here but may not be essentially formed of Cu. The conduction layer 18a may be formed of, e.g., Cu alloy film. The Cu alloy film can be formed of, e.g., an alloy of Cu and Al or others.

On the inter-layer insulation film 12, a barrier film 20a of a conductive material for preventing the diffusion of Cu is formed, covering the conduction layer 18a. The barrier film 20a is formed solid. The barrier film 20a is formed of a film containing, e.g., Ta, TaN, TiN or others. The film thickness of the barrier film 20a is, e.g., about 50-200 nm.

The conduction layer 18a and the barrier film 20a form the lower electrode 22 of the capacitance element 28.

The surface of the barrier film 20a is polished by CMP and is planarized. A good dielectric film 24a is formed on the barrier film 20a, whose surface is sufficiently planarized. The planarized surface of the barrier film 20a contributes to improving the reliability and the electric characteristics of the capacitance element 28.

The surface of the barrier film 20a is planarized by polishing here, but the surface of the barrier film 20a may not be essentially polished.

On the barrier film 20a, a dielectric film (capacitor insulation film) 24a is formed. The film thickness of the dielectric film 24a is, e.g., about 20-60 nm. The dielectric film 24a is formed of, e.g., silicon oxide film, silicon nitride film or others.

On the dielectric film 24a, an upper electrode 26a of a conduction layer is formed. The thickness of the upper electrode 26a is, e.g., about 50-200 nm. The upper electrode 26a is formed of a film containing, e.g., Ta, TaN, TiN or others.

The upper electrode 26a is formed of a single conduction film here, but the structure of the upper electrode 26a is not limited to such structure. For example, the upper electrode 26a may be formed of the layer film of a conduction film and an insulation film sequentially stacked. Such insulation film can be, e.g., SiN film, SiC film or others.

Thus, the capacitance element 28 including the lower electrode 22, the dielectric film 24a and the upper electrode 26a is constituted.

Next, the interconnections 18b will be described.

As illustrated in FIG. 1B, in the inter-layer insulation film 12 in the regions 4 where the interconnections to be formed, the trenches 14b with the interconnections 18b buried in are formed. Such trenches 14b are formed, e.g., linear.

In the trenches 14b, the barrier metal film 16 of a conductive material for the prevention of the diffusion of Cu is formed. The barrier metal film 16 is formed of, e.g., Ta film, TaN film or others.

In the trenches 14b with the barrier metal film 16 formed in, the interconnections 18b containing Cu are formed. The interconnections 18b are formed of Cu here.

The interconnections 18b are formed of Cu here, but the material of the interconnections 18b is not limited to Cu. The interconnections 18b may be formed of, e.g., Cu alloy or others.

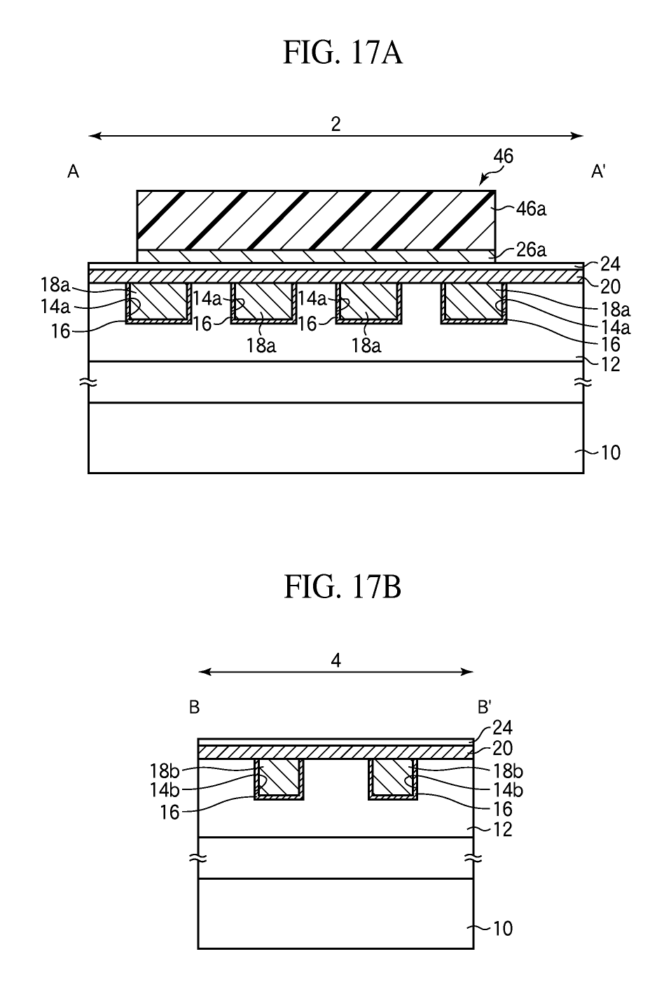

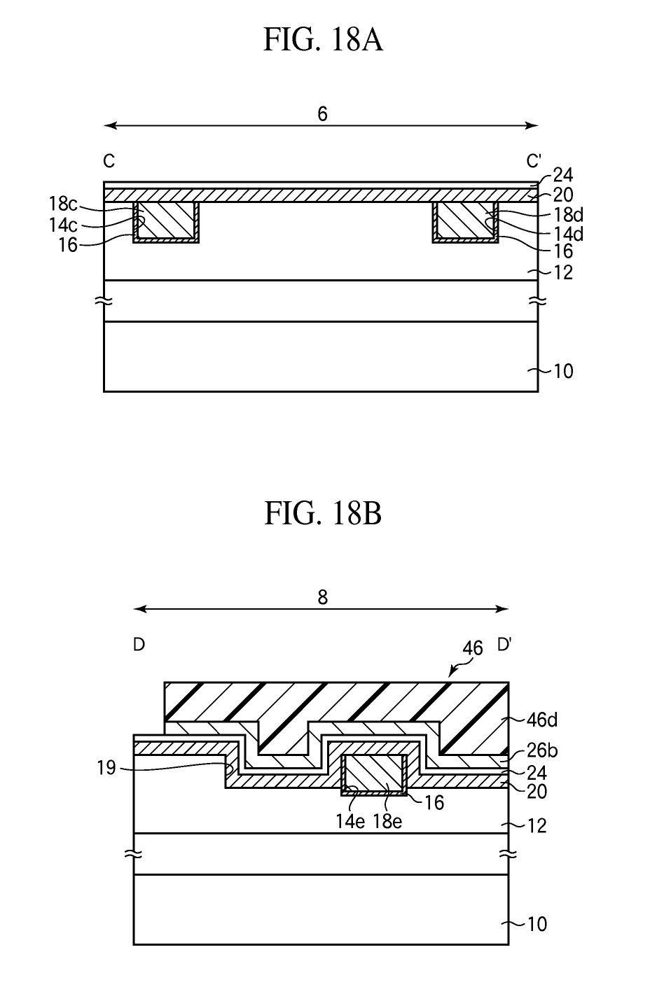

On the inter-layer insulation film 12, the barrier film 20b of a conductive material of the prevention of the diffusion of Cu is formed so as to cover the interconnection 18b. The barrier film 20b is formed along the interconnections 18b. The barrier film 20b is formed of a film containing Ta, TaN, TiN or others. The film thickness of the barrier film 20b is, e.g., about 50-200 nm. The barrier film 20b is formed of one and the same conduction film as the barrier film 20a. That is, the barrier film 20a formed covering the conduction layer 18a, and the barrier film 20b formed covering the interconnections 18b are formed by patterning one and the same barrier metal film 20 (see FIGS. 17A to 18B).

On the barrier film 20b, the dielectric film 24b is formed. The film thickness of the dielectric film 24b is, e.g., about 20-60 nm. The dielectric film 24b is formed of, e.g., silicon oxide film, silicon nitride film or others. The dielectric film 24b is formed of the one and the same dielectric film of the dielectric film 24 of the capacitance element 28. That is, the dielectric film 24a on the barrier film 20a, and the dielectric film 24b on the barrier film 20b are formed by patterning one and the same dielectric film 24 (see FIGS. 17A to 18B).

Thus, the interconnections 18b are formed.

Next, the resistance device 30 will be described.

As illustrated in FIG. 2A, in the region 6 where the resistance element to be formed, trenches 14c, 14d for interconnections 18c, 18d buried in are formed. The trenches 14c, 14d are formed, e.g., linear.

In the trenches 14c, 14d, the barrier metal film 16 formed of a conductive material for preventing the diffusion of Cu is formed. The barrier metal film 16 is formed of, e.g., Ta film, TaN film or others.

In the trenches 14c, 14d with the barrier metal film 16 formed in, the interconnections 18c, 18d containing Cu are buried in. The interconnections 18c, 18d are formed of Cu here.

The interconnections 18c, 18d are formed of Cu here, but the material of the interconnections 18c, 18d is not limited to Cu. The interconnections 18c, 18d may be formed of, e.g., Cu alloy film or others.

On the inter-layer insulation film 12, a resistance layer 20c of a conductive material for preventing the diffusion of Cu is formed. The resistance layer 20c is formed from one interconnection 18c to the other interconnection 18d, covering one interconnection 18c and the other interconnection 18d. The resistance layer 20c is formed, covering the interconnections 18c, 18d for preventing the diffusion of Cu from the interconnections 18c, 18d. The resistance layer 20c is formed of a film containing, e.g., Ta, TaN, TiN or others. The thickness of the resistance layer 20c is, e.g., about 50-200 nm. The resistance layer 20c is formed of one and the same conduction film as the barrier film 20a, 20b. That is, the barrier film 20a formed covering the conduction layer 18a, and the barrier film 20b formed covering the interconnection 18b, and the resistance layer 20c are formed by patterning one and the same barrier metal film 20 (see FIGS. 17A to 18B).

On the resistance layer 20c, a dielectric film 24c is formed. The film thickness of the dielectric film 24c is, e.g., about 20-60 nm. The dielectric film 24c is formed of, e.g., silicon oxide film, silicon nitride film or others. The dielectric film 24c is formed of one and the same dielectric film as the dielectric films 24a, 24b. That is, the dielectric film 24a on the barrier film 20a, the dielectric film 24b on the barrier film 20b, and the dielectric film 24c on the resistance layer 20c are formed by patterning one and the same dielectric film 24 (see FIGS. 17A to 18B).

Thus, the resistance device 30 including the resistance layer 20c is formed.

Next, the alignment mark 18e will be described.

The alignment mark 18e is used in the alignment or others of a reticle or others.

As illustrated in FIG. 2B, in a region 8 where an alignment mark to be formed, a trench 14e for the alignment mark 18e buried in is formed. The pattern of the trench 14e is, e.g., ring-shaped (see FIGS. 3 and 4).

In the trench 14e, the barrier metal film 16 of a conductive material for preventing the diffusion of Cu is formed. The barrier film 16 is formed of, e.g., Ta film, TaN film or others.

In the trench 14e with the barrier metal film 16 formed in, the alignment mark 18e containing Cu is buried. The alignment mark 18e is formed of Cu here.

The alignment mark 18e is formed of Cu here, but the material of the alignment mark 18e is not limited to Cu. The alignment mark 18e may be formed of, e.g., Cu alloy, etc.

The inter-layer insulation film 12 around the alignment mark 18e is etched, exposing an upper part of the alignment mark 18e. The upper part of the alignment mark 18e is projected upward of the upper surface of the inter-layer insulation film 12. A step 19 is formed in the surface of the inter-layer insulation film 12 around the alignment mark 18e.

On the inter-layer insulation film 12 and the alignment mark 18e, a barrier film 20d of a conductive material for preventing the diffusion of Cu is formed. The barrier film 20d is formed of a film containing, e.g., Ta, TaN, TiN or others. The film thickness of the barrier film 20d is, e.g., about 50-200 nm. The barrier film 20d is formed of one and the same conduction film as the barrier films 20a, 20b and the resistance layer 20c. That is, the barrier film 20a formed covering the conduction layer 18a, the barrier film 20b formed covering the interconnections 18b, the resistance layer 20c, and the barrier film 20d covering the alignment mark are formed of by patterning one and the same barrier metal film 20 (see FIGS. 17A to 18B).

On the barrier film 20d, a dielectric film 24d is formed. The film thickness of the dielectric film 24d is, e.g., about 20-60 nm. The dielectric film 24d is formed of, e.g., silicon oxide film, silicon nitride film or others. The dielectric film 24d is formed of one and the same dielectric film as the dielectric films 24a-24c. The dielectric film 20a on the barrier film 18a, the dielectric film 24b on the barrier film 20b, the dielectric film 24c on the resistance layer 20c, and the dielectric film 24d on the barrier film 20d are formed by patterning one and the same dielectric film 24 (see FIGS. 17A to 18B).

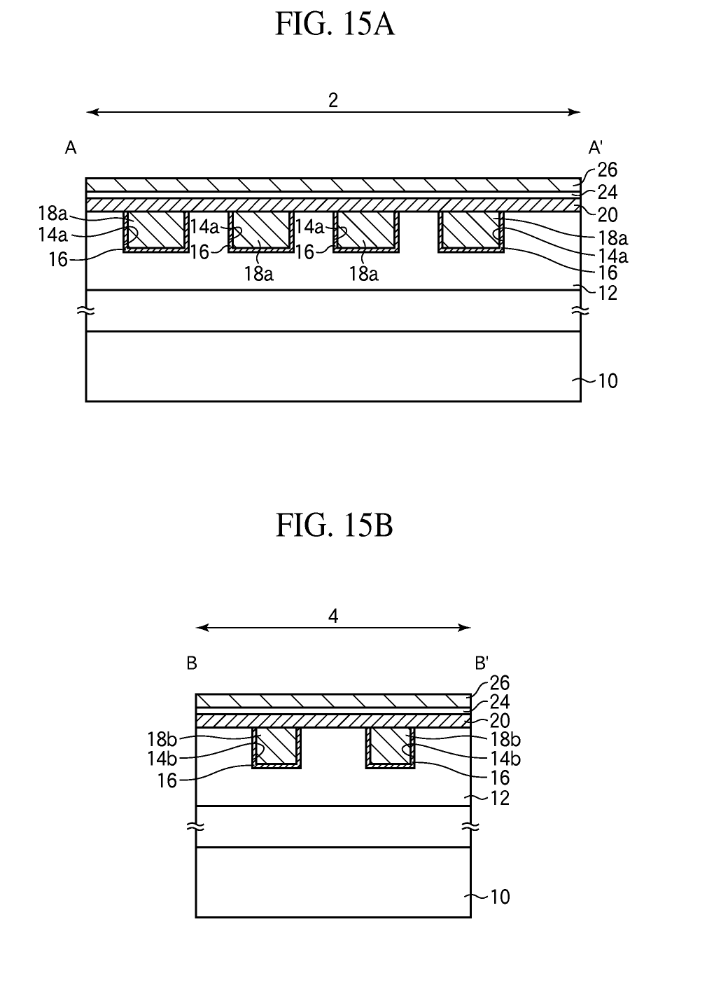

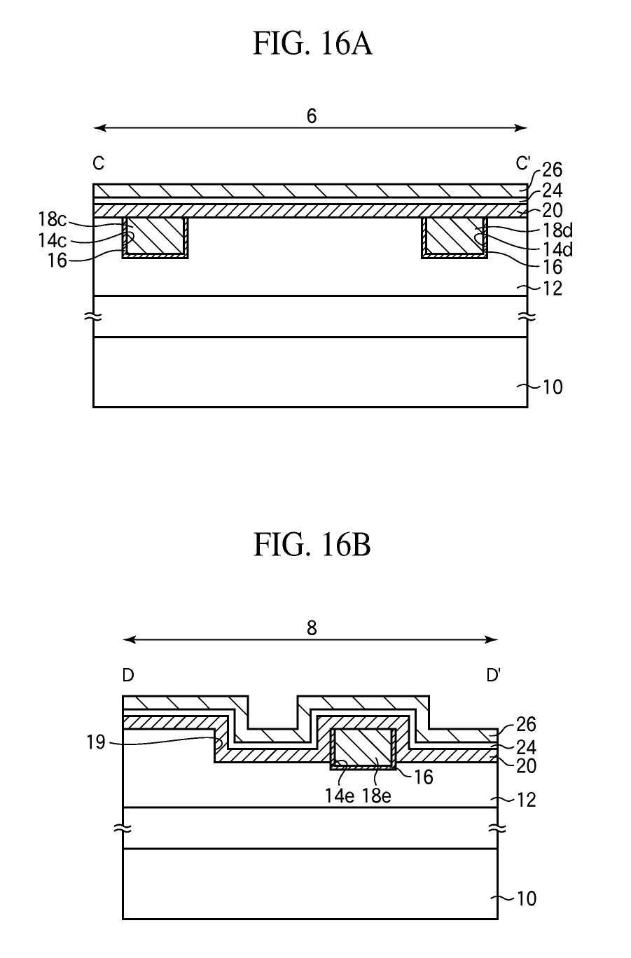

On the dielectric film 24d, a conduction layer 26b is formed. The thickness of the conduction layer 26b is, e.g., about 50-200 nm. The conduction layer 26b is formed of, e.g., a film containing Ta, TaN, TiN or others. The conduction layer 26b is formed of one and the same conduction layer as the upper electrode 26a of the capacitance element 28. That is, the conduction layer 26b formed on the alignment mark 18e, and the upper electrode 26a of the capacitance element 28 are formed by patterning one and the same conduction layer 26 (see FIGS. 15A to 16B).

Thus, the alignment mark 18e is formed.

On the semiconductor substrate 10 with the capacitance element 28, the interconnections 18b, the resistance device 30 and the alignment mark 18e formed on, an inter-layer insulation film 34 is formed. The inter-layer insulation film 34 is formed of, e.g., silicon oxide film. The surface of the inter-layer insulation film 34 is planarized by, e.g., CMP.

In the region 2 where the capacitance element is formed, contact holes 36a are formed in the inter-layer insulation film 34 down to the upper electrode 26a. In the region 2 where the capacitance element to be formed, a number of the contact holes 36a are formed. A number of the contact holes 36a are formed in the region 2 for the capacitance element to be formed in so as to sufficiently reduce the electric resistance between an interconnection 40a formed above the capacitance element 28 and the upper electrode 26a of the capacitance element 28. In the region 2 for the capacitance element to be formed in, contact holes 36b arriving at the lower electrode 22 are formed in the inter-layer insulation film 34 and the dielectric film 24a (see FIG. 4).

In the region 4 with the interconnections formed in, contact holes 36c arriving at the barrier film 20b on the interconnections 18b are formed in the inter-layer insulation film 34 and the dielectric film 24b.

In the contact holes 36a-36c, conductor plugs 38a-38c of, e.g., tungsten are respectively buried.

In the region 2 for the capacitance element to be formed in, contact holes 40a, 40b are formed respectively on the inter-layer insulation film with the conductor plugs 38a, 38b buried in (see FIG. 1B and 4). The interconnection 40a is connected to the upper electrode 26a of the capacitance element 28 via the conductor plugs 38a.

The interconnection 40b is connected to the lower electrode 22 of the capacitance element 28 via the conductor plugs 38b. The interconnections 40a, 40b are formed of the layer film of, a Ti film, the first TiN film, an Al film and the second TiN film sequentially stacked. The film thickness of such Ti film is, e.g., about 30 nm. The film The film thickness of the first TiN film is, e.g., about 60 nm. The film thickness of the Al film is, e.g., about 1000 nm. The film thickness of the second TiN film is, e.g., about 50 nm.

In the region 4 with the interconnections formed in, an interconnection 40c is formed on the inter-layer insulation film 34 with the conductor plugs 38c buried in. The interconnection 40c is formed of the same material as the interconnections 40a, 40b described above.

Thus, the semiconductor device according to the present embodiment is constituted.

As described above, according to the present embodiment, the barrier film 20a of a conductive material for preventing the diffusion of Cu is formed, covering the conduction layer 18a containing Cu, and the conduction layer 18a and the barrier film 20a form the lower electrode 22 of the capacitance element 28. According to the present embodiment, the barrier film 20a for preventing the diffusion of Cu is formed of a conductive material, which makes it unnecessary to etch off the barrier film on the conduction layer 18a. Thus, according to the present embodiment, the conduction layer 18a is protected from being damaged by etching, and the capacitance element 28 can have good electric characteristics. Furthermore, according to the present embodiment, the barrier film 20b of a conductive material for preventing the diffusion of Cu is formed, covering the interconnections 18b, which makes it possible to prevent the diffusion of the Cu contained in the interconnections 18b by the barrier film 20b. Thus, the present embodiment can provide a semiconductor device including a capacitance element of good electric characteristics without impairing the reliability.

(Method for Manufacturing the Semiconductor Device)

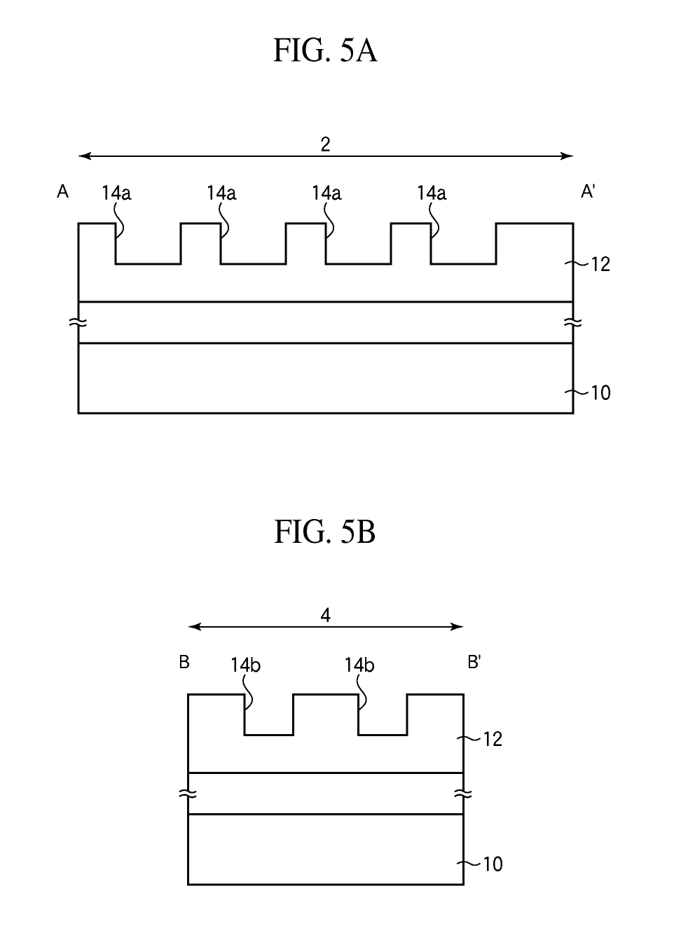

Next, the method for manufacturing the semiconductor device according to the present embodiment will be described with reference to FIGS. 5A to 24B. FIGS. 5A to 24B are sectional views of the semiconductor device according to the present embodiment in the steps of the method for manufacturing the semiconductor device, which illustrate the method.

First, on the semiconductor substrate 10 with transistors (not illustrated), etc. formed on, a multilayer interconnection structure (not illustrated) is formed.

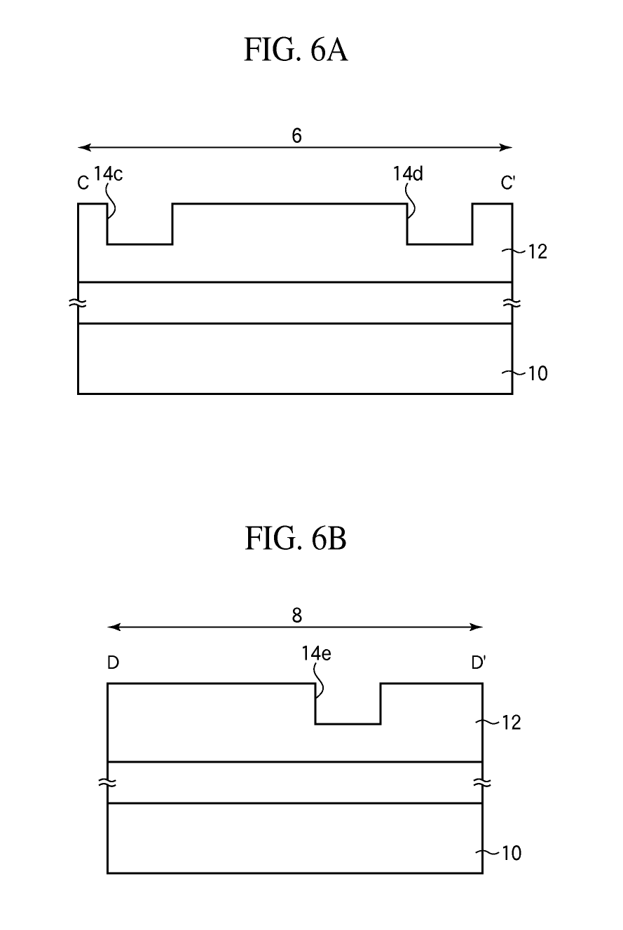

Next, by photolithography, the trenches 14a-14e are formed in the upper inter-layer insulation film 12 (see FIGS. 5A to 6B).

In the region 2 for the capacitance element to be formed in, the trenches 14a where the conduction layer 18a forming a part of the lower electrodes 22 are to be buried in is formed (see FIG. 5A). The trenches 14a are formed, enclosing parts of the inter-layer insulation film 12.

In the region 4 for the interconnections to be formed in, the trenches 14b for the interconnections 18b to be buried in are formed (see FIG. 5B). The trenches 14b are formed, e.g., linearly. The width of the trenches 14b for the interconnections 18b to be buried in is, e.g., about 0.4 μm. The distance between the trenches 14b adjacent to each other is, e.g., about 0.4 μm.

In the region 6 for the resistance element to be formed in, the trenches 14c, 14d for the interconnections 18c, 18d to be buried in are formed (see FIG. 6A). The trenches 14c, 14d are formed, e.g., linearly.

In the region 8 for the alignment mark to be formed in, the trench 14 for the alignment mark 18e to be buried in is formed (see FIG. 6B). The trench 14e is formed in, e.g., a rectangle.

The depth of the trenches 14a-14e is, e.g., about 0.5-4.0 μm.

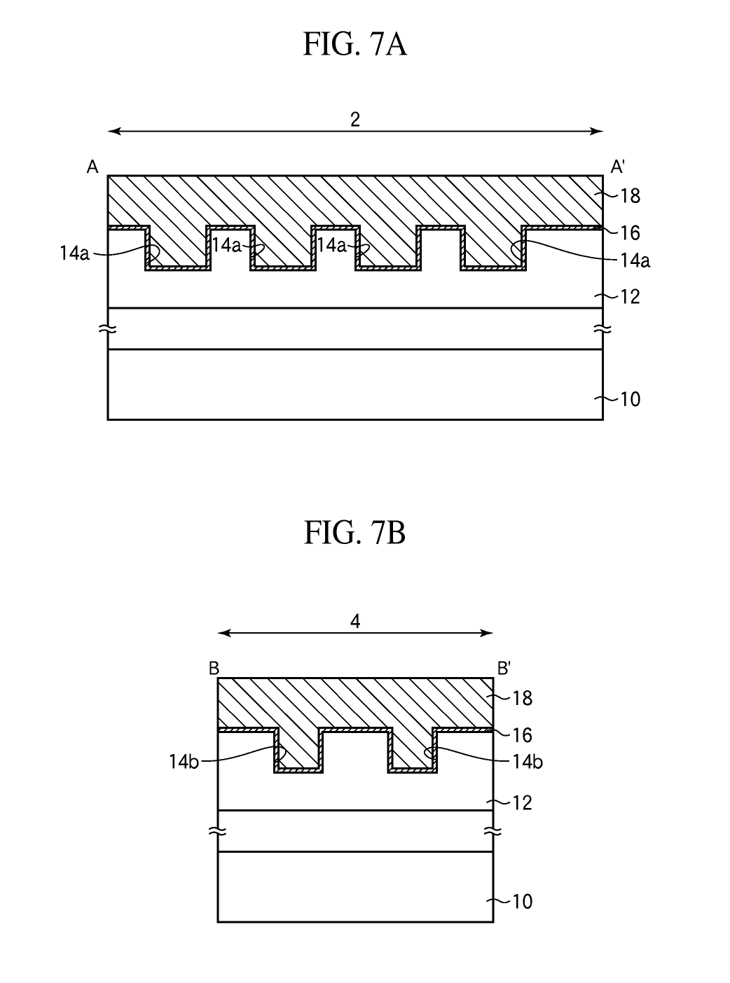

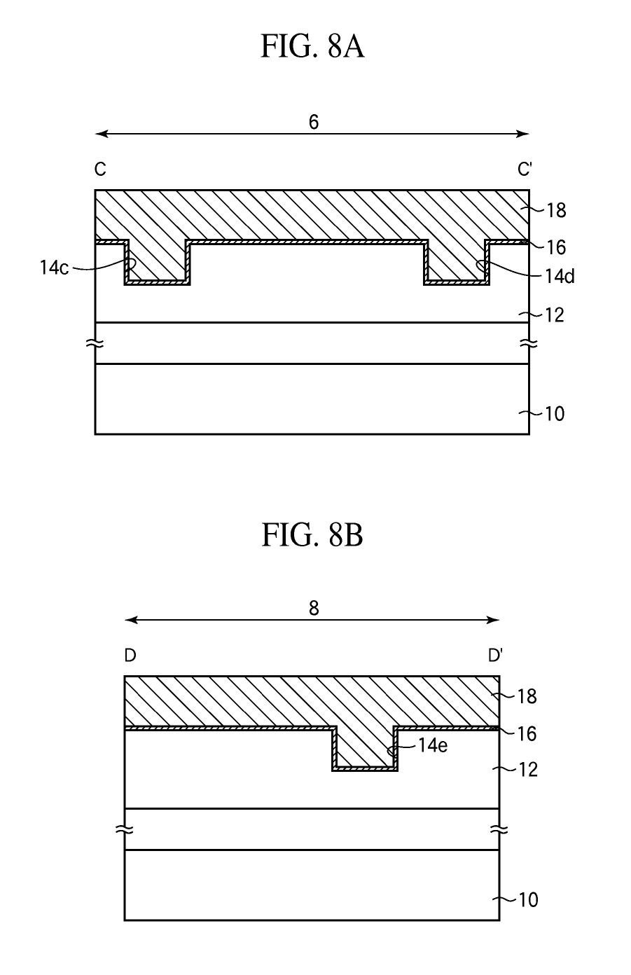

Then, on the entire surface, the barrier metal film 16 is formed by, e.g., sputtering (see FIGS. 7A to 8B). The barrier metal film 16 is formed of, e.g., Ta film, TaN film, TiN film or others. The film thickness of the barrier metal film 16 is, e.g., about 5-70 nm.

Then, on the entire surface, the seed layer of Cu (not illustrated) is formed by, e.g., sputtering.

Next, the conduction layer 18 containing Cu is formed by electroplating. The conduction layer 18 is formed of a Cu layer. The material of the conduction layer 18 is not limited to Cu. The conduction layer 18 may be formed of Cu alloy. The thickness of the conduction layer 18 is, e.g., about 0.7-6.0 μm.

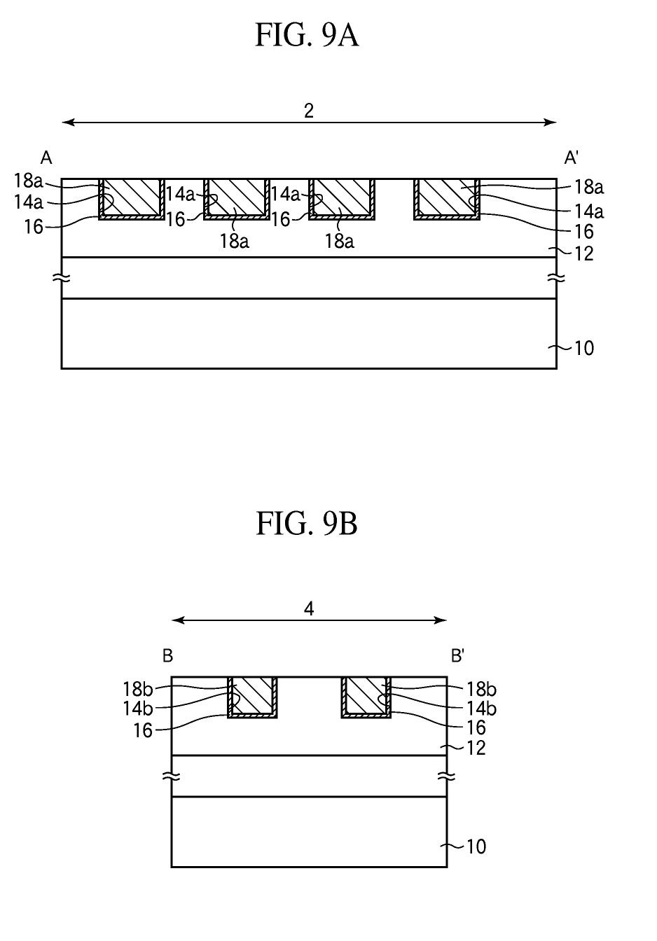

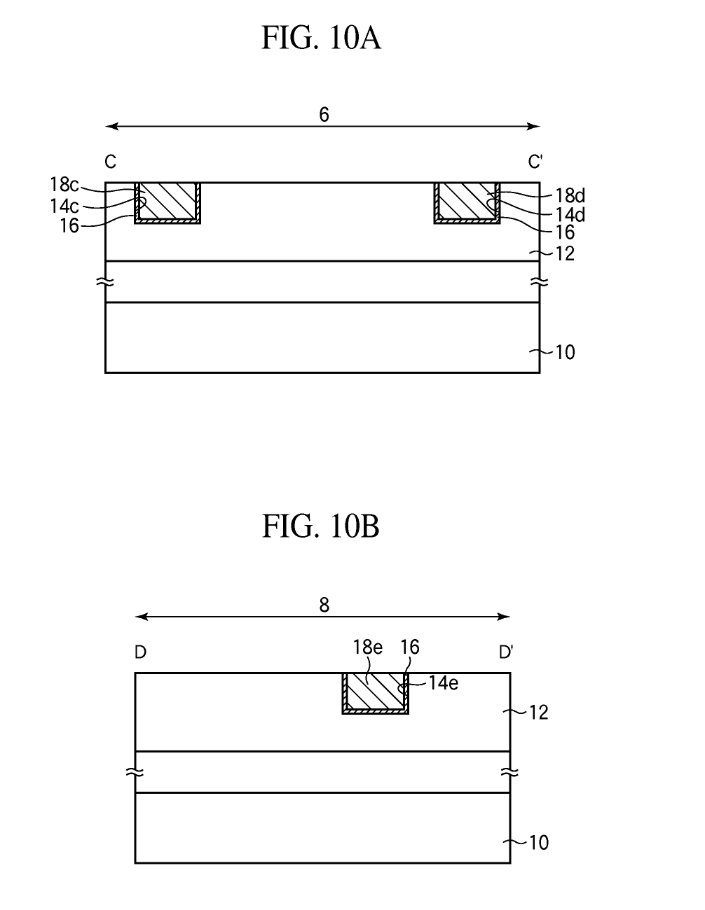

Then, the conduction layer 18 is polished by CMP until the surface of the inter-layer insulation film 12 is exposed (see FIGS. 9A to 10B). Thus, the conduction layer 18a containing Cu is buried in the trenches 14a (see FIG. 9A). The interconnections 18b containing Cu are buried in the trenches 14b (see FIG. 9B). The interconnections 18c, 18d containing Cu are buried respectively in the trench 14c, 14d. (see FIG. 10A). The alignment mark 18e containing Cu is buried in the trench 14e (see FIG. 10B).

Then, a photoresist film 42 is formed on the entire surface by spin coating.

Next, by photolithography, an opening 44 is formed in the photoresist film 42. The opening 44 is formed, exposing the alignment mark 18e and the surroundings of the alignment mark 18e.

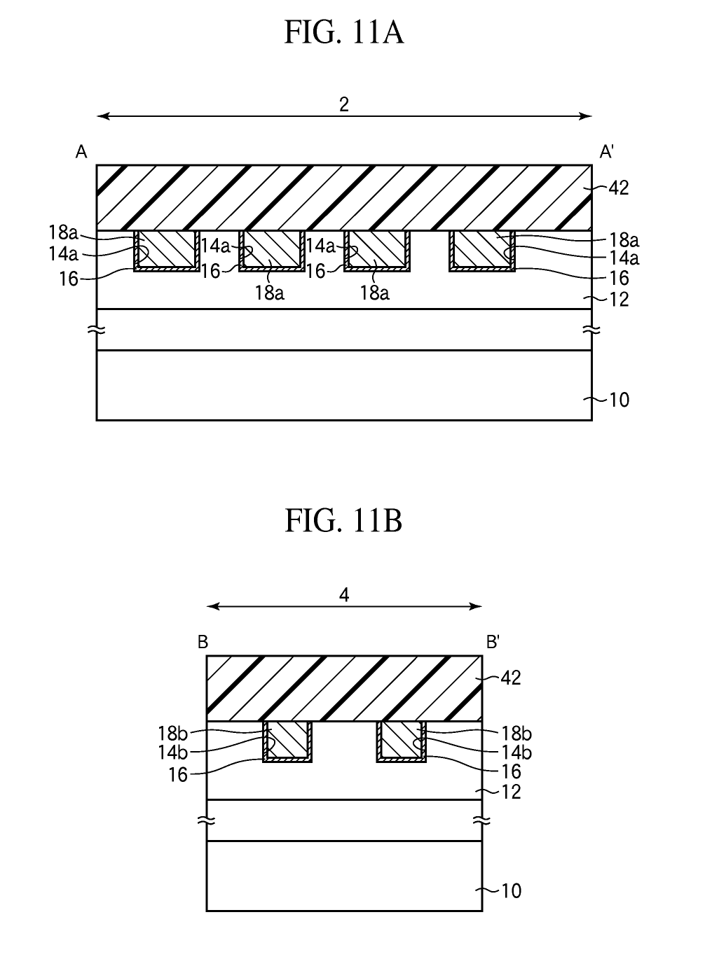

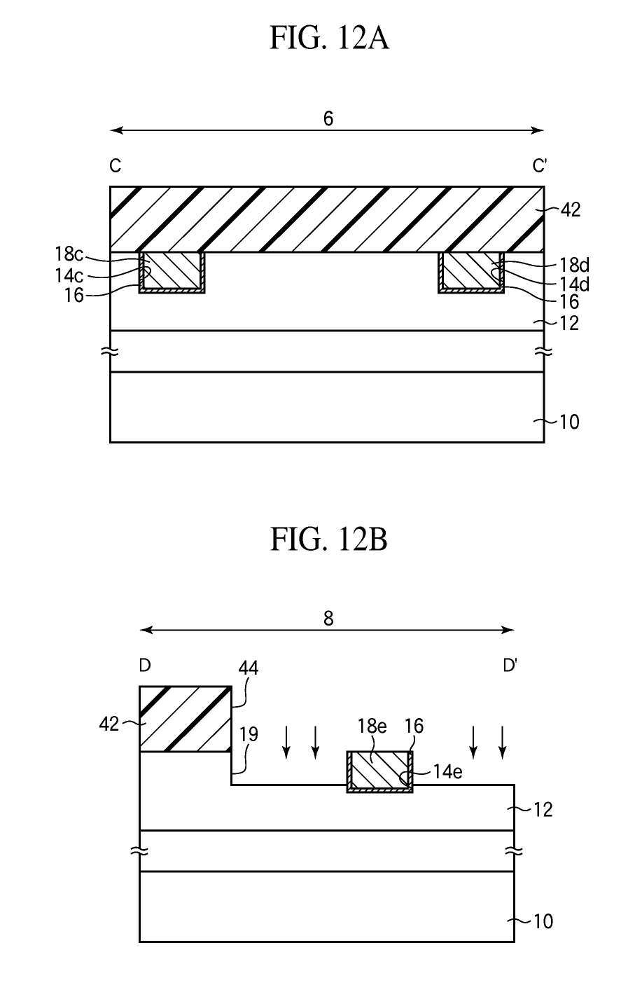

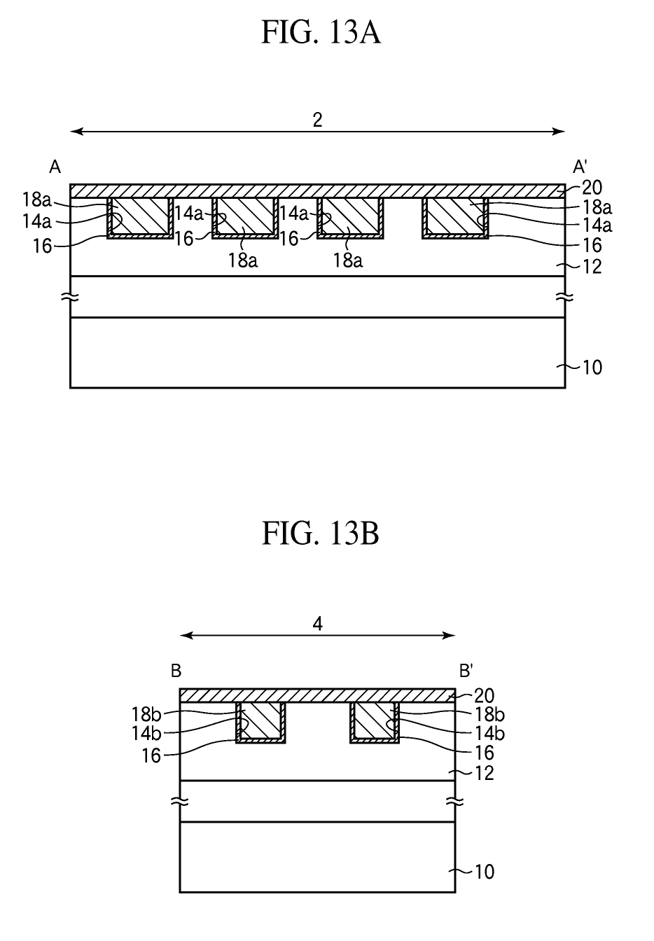

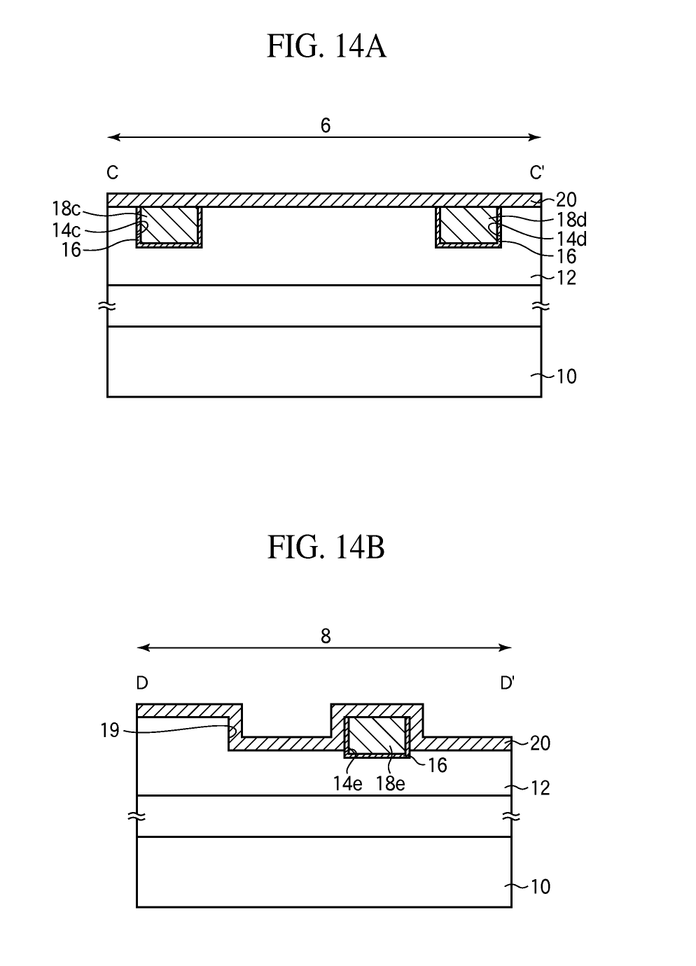

Then, with the photoresist film 42 as the mask, the inter-layer insulation film 12 in the surroundings of the alignment mark 18e is etched (see FIGS. 11A to 12B). The etch amount for etching the inter-layer insulation film 12 is set smaller than the height of the alignment mark 18e. Thus, the upper part of the alignment mark 18e is projected beyond the inter-layer insulation film 12. A step 19 is formed in the surface of the inter-layer insulation film 12 around the alignment mark 18e. According to the present embodiment, the alignment mark 18e formed, projected beyond the inter-layer insulation film 12, which makes it possible for the alignment mark 18e to surely do the aligning function even when the alignment mark 18e is covered by the barrier metal film 20 (see FIGS. 13A to 14B), the conduction layer 26 (see FIGS. 15A to 16B), etc. in later steps. Then, the photoresist film 42 is released.

Next, the barrier metal film 20 is formed by, e.g., sputtering (see FIGS. 13A to 14B). The barrier metal film 20 is formed of a film containing, e.g., Ta, TaN, TiN or others. The barrier metal film 20 is for preventing the diffusion of Cu from the conduction layer 18a, the interconnections 18b-18d, the alignment mark 18e, etc. buried in the inter-layer insulation film 12.

Next, by, e.g., CMP the surface of the barrier metal film 20 is polished. Thus, the surface of the barrier metal film 20 is planarized.

The surface of the barrier metal film 20 is planarized by CMP here but may not be essentially planarized by CMP. The surface of the barrier metal film 20 may be planarized suitably as required. However, when the surface of the barrier metal film 20 is not sufficiently flat, preferably, the surface of the barrier metal film 20 is planarized by CMP.

Then, the dielectric film 24 is formed by, e.g., plasma enhanced CVD (Chemical Vapor Deposition) (see FIGS. 15A to 16B). The dielectric film 24 is formed of, e.g. silicon oxide film, silicon nitride film or others. The film thickness of the dielectric film 24 is, e.g., about 20-60 nm. When the dielectric film 24 of silicon oxide film is formed by plasma enhanced CVD, TEOS gas, for example, is used. When the dielectric film 24 of silicon nitride film is formed by plasma enhanced CVD, SiH₄ gas and NH₃ gas, for example, are used.

Then, the conduction layer 26 is formed by, e.g., sputtering. The conduction layer 26 is formed of a film containing, e.g., Ta, TaN, TiN or others. The thickness of the conduction layer 26 is, e.g., about 50-200 nm.

Next, a photoresist film 46 is formed by spin coating.

Then, the photoresist film 46 is patterned by photolithography (see FIGS. 17A to 18B). In the region 2 for the capacitance element to be formed in, the pattern 46a of the photoresist film is formed in a plane shape of the upper electrode 26a of the capacitance element 28 (see FIG. 17A). In the region 8 for the alignment mark to be formed in, the pattern 46b of the photoresist film is formed, covering the alignment mark 18e and the surroundings of the alignment mark 18e (see FIG. 18B).

Then, by, e.g., RIE (Reactive Ion Etching), the conduction layer 26 is etched with the photoresist mask 46 as the mask. The etching gas is, e.g., CF₄ gas.

The etching gas is CF₄ gas here, but the etching gas is not limited to CF₄ gas. For example, the mixed gas of CF₄ gas and 0₂ gas may be used as the etching gas.

Thus, in the region 2 for the capacitance element to be formed in, the upper electrode 26a of the conduction layer is formed. In the region 8 for the alignment mark to be formed in, the conduction layer 26b is formed, covering the alignment mark 18e and the surroundings of the alignment mark 18e.

Then, the photoresist film 46 is released.

Next, the photoresist film 48 is formed by spin coating.

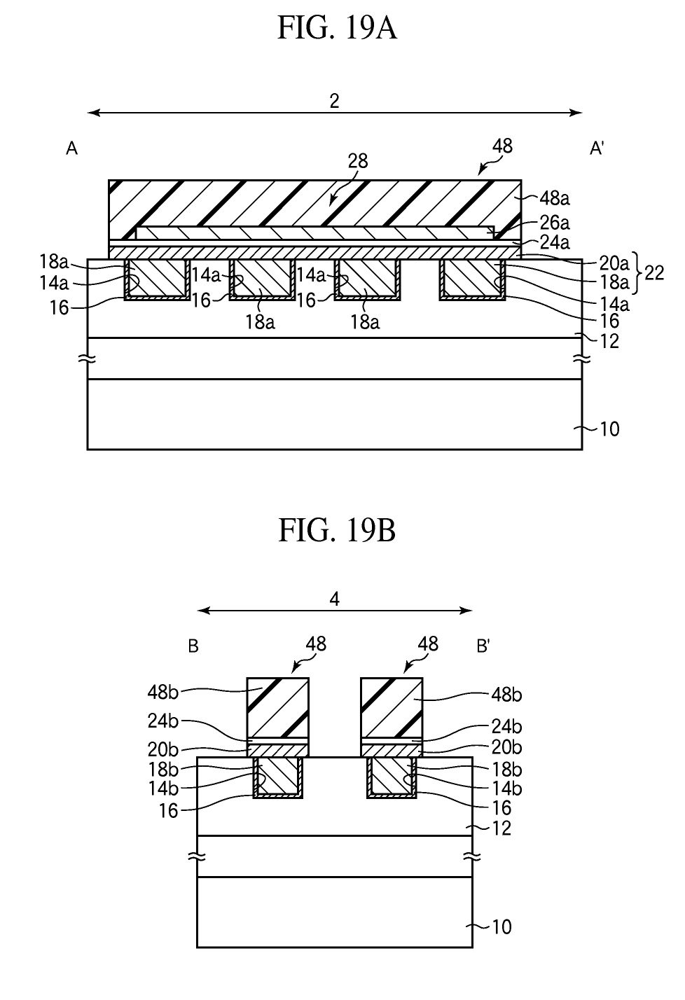

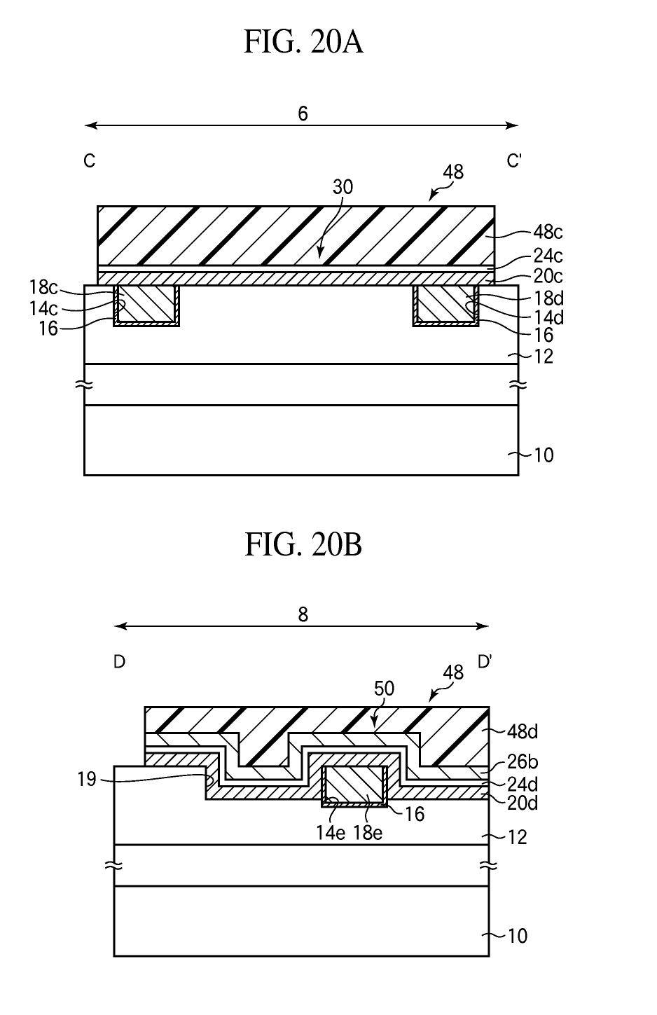

Next, the photoresist film 48 is patterned by photolithography (see FIGS. 19A to 20B). In the region 2 for the capacitance element to be formed in, a pattern 48a formed of the photoresist film 48 is formed in plane shapes of the barrier films 18a forming a part of the lower electrode 22 of the capacitance element 28 (see FIG. 19A). In the region 4 for the interconnections to be formed in, patterns 48b formed of the photoresist film 48 are formed along the interconnections 18b (see FIG. 19B). The width of the patterns 48b in the region 4 for the interconnections to be formed in is set larger than the width of the interconnections 28b. More specifically, the width of the patterns 48b is set larger by, e.g., 0.16 μm than the width of the interconnections 18b. In the region 6 for the resistance element to be formed in, a pattern 48c formed of the photoresist film 48 is formed in a plane shape of the resistance layer 20c (see FIG. 20A). In the region 8 for the alignment mark 18e to be formed in, a pattern 48d formed of the photoresist film 48 is formed, covering the alignment mark 18e and the surroundings of the alignment mark 18e (see FIG. 20B).

Next, by, e.g., RIE, the dielectric film 24 and the barrier metal film 20 are etched with the photoresist film 48 as the mask. When the dielectric film 24 is formed of silicon oxide film, the dielectric film 24 is etched with, e.g., CF₄ gas. When the barrier metal film 20 is etched, CF₄ gas, for example, is used.

The dielectric film 24 is etched with CF₄ gas here, but the etching gas used in etching the dielectric film 24 is not limited to CF₄ gas. The dielectric film 24 may be etched with, e.g., the mixed gas of CF₄ gas and H₂ gas.

The barrier metal film 20 is etched with CF₄ gas here. The etching gas to be used in etching the barrier metal film 20 is not limited to CF₄ gas. The barrier metal film 20 may be etched with, e.g., the mixed gas of CF₄ gas and O₂ gas.

Thus, in the region for the capacitance element 2 to be formed in, the barrier film 20a of the barrier metal film 20 is formed, covering the conduction layer 18a. The barrier film 20a forms, in cooperation with the conduction layer 18a, the lower electrode 22 of the capacitance element 28. In the region 2 for the capacitance element to be formed in, the capacitance element 28 including the lower electrode 22, the dielectric film 24a and the upper electrode 26a is formed (see FIG. 19A). In the region 4 for the interconnections to be formed in, the barrier film 20b formed of the barrier metal film 20 is formed along the interconnections 18b (see FIG. 19B). In the region 6 for the resistance element to be formed in, the resistance layer 20c formed of the barrier metal film 20 is formed (see FIG. 20A). The resistance layer 20c is formed in the region from one interconnection 18c to the other interconnection 18d and also along one interconnection 18c and the other interconnection 18d. That is, the interconnections 18c, 18d buried in the region 6 for the resistance element to be formed in are covered by the barrier film 20c. In the region 8 for the alignment mark to be formed in, the alignment mark 18e is covered by the barrier metal film 20d, the dielectric film 24d and the conduction layer 26b (see FIG. 20B). Because of the alignment mark 18e formed projected beyond the inter-layer insulation film 12, the surface of the conduction layer 20d covering the alignment mark 18e has a convexity 50. Thus, according to the present embodiment, the alignment mark 18e is covered by the conduction layer 26b, but the position where the alignment mark 18e is formed can be recognized.

Then, the photoresist film 48 is released.

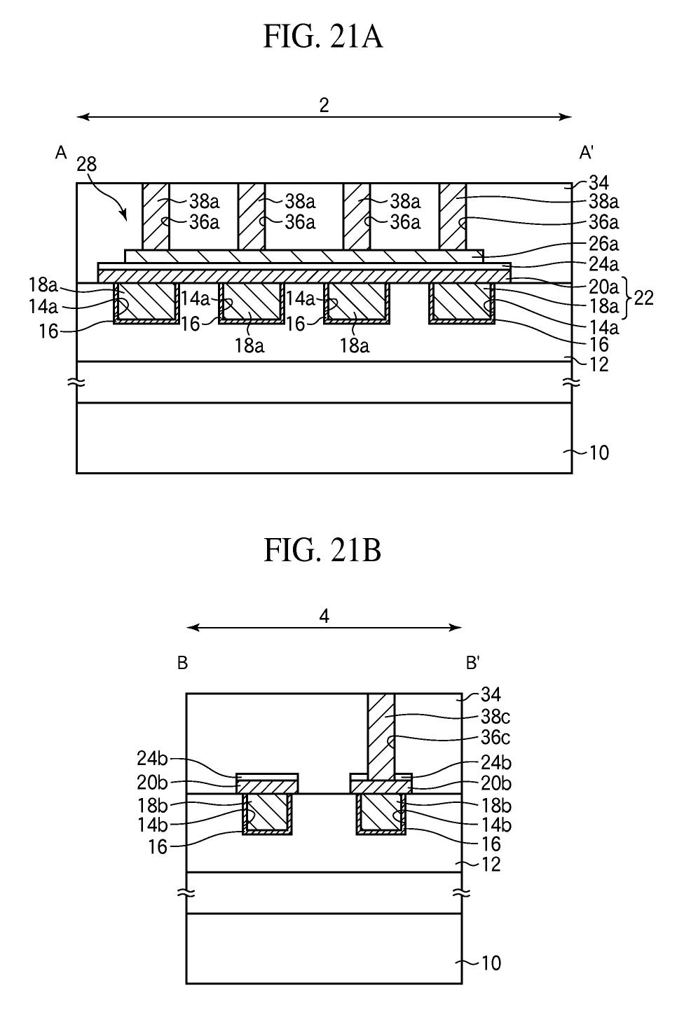

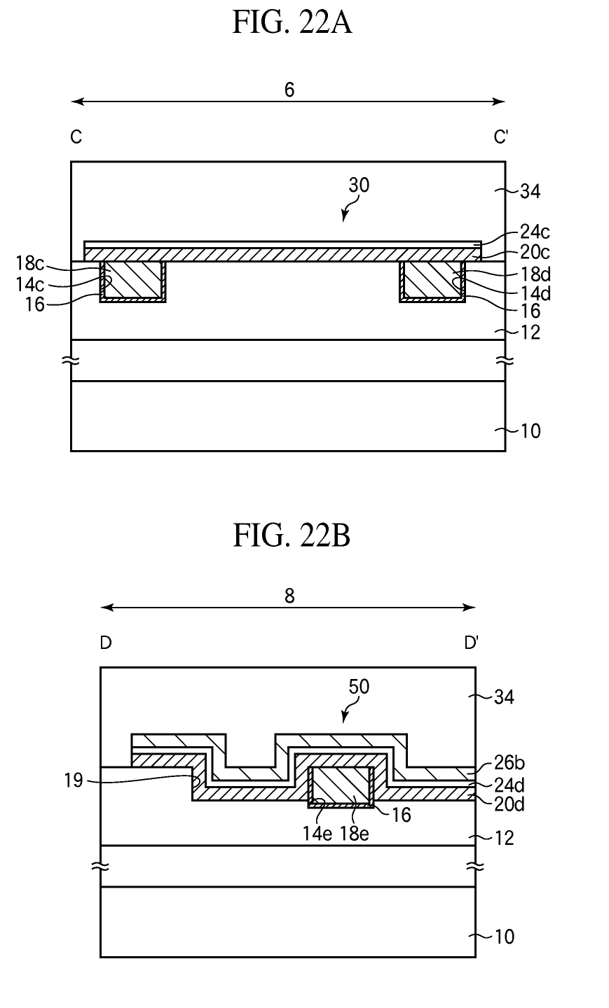

Next, the inter-layer insulation film 34 of, e.g., silicon oxide film is formed by, e.g., plasma enhanced CVD (see FIGS. 21A to 22B). TEOS gas, for example, is sued in forming the inter-layer insulation film 34 of silicon oxide film.

Next, the surface of the inter-layer insulation film 34 is polished by, e.g., CMP. Thus, the surface of the inter-layer insulation film 34 is planarized.

Then, by photolithography, the contact holes 36a arriving at the upper electrode 26a of the capacitance element 28, the contact holes 36b arriving at the lower electrode 22 of the capacitance element 28 (see FIG. 4), and the contact holes 36c arriving at the barrier film 20b on the interconnections 18b are respectively formed in the inter-layer insulation film 34. The diameter of the contact holes 36a-36c is, e.g., about 0.28-0.40 μm. As the etching gas to be used in forming the contact holes 36a-36c, CF₄ gas, for example, is used.

CF₄ gas is used here in forming the contact holes 36a-36c. The etching gas to be used in forming the contact holes 36a-36c is not limited to CF₄ gas. The mixed gas of CF₄ gas and H₂ gas, for example, may be used as the etching gas.

Then, a tungsten film is formed by, e.g., CVD. The film thickness of the tungsten film is, e.g., about 500-800 nm. As the gas to be fed into the film forming chamber when the tungsten film is formed, a mixed gas containing, e.g., WF₆ gas and H₂ gas is used.

Then, the tungsten film is polished by, e.g., CMP until the surface of the inter-layer insulation film 34 is exposed. Thus, the conductor plugs 38a of tungsten are buried in the contact holes 36a, the conductor plugs 38b of tungsten are buried in the contact holes 36b, and the conductor plugs 38c of tungsten are buried in the contact holes 36c.

Then, by, e.g., sputtering, a Ti film, the first TiN film, an Al film and the second TiN film are sequentially formed to form a layer film. The film thickness of the Ti film is, e.g., about 30 nm. The film thickness of the first TiN film is, e.g., about 60 nm. The film thickness of the Al film is, e.g., about 1000 nm. The film thickness of the second TiN film is, e.g., about 50 nm.

Next, the layer film is patterned by photolithography. For patterning the layer film, RIE, for example, is used. As the etching gas used in patterning the layer film, BCl₃ gas, for example, is used.

BCl₃ gas is used here in patterning the layer film. The gas used in patterning the layer film is not limited to BCl₃ gas. Cl₂ gas, for example, may be used in patterning the layer film.

Thus, the interconnections 40a-40c formed of the layer film are formed (see FIGS. 4, 23A to 24B). The interconnection 40a is electrically connected to the upper electrode 26a of the capacitance element 28 via the conductor plugs 38a. The interconnection 40b is electrically connected to the lower electrode 22 of the capacitance element 28 via the conductor plugs 38b (see FIG. 4). The interconnection 40c is electrically connected to the interconnections 18b via the conductor plugs 38c and the barrier film 20b.

Thus, the semiconductor device according to the present embodiment is manufactured.

According to the present embodiment, the barrier metal film 20 formed of a conductive material for preventing the diffusion of Cu is formed on the entire surface, and the barrier metal film 20 is patterned, whereby the barrier film 20a covering the conduction layer 18a and the barrier film 20b covering the interconnections 18b are formed. Thus, the conduction layers 18a are prevented from being damaged by etching, whereby the semiconductor device including the capacitance element 28 having good electric characteristics can be manufactured.

### Modified Embodiments

The present invention is not limited to the above-described embodiments and can cover other various modifications.

For example, in the above-described embodiments, the conduction layer 26b remains in the region 8 where the alignment mark is formed, but the conduction layer may not remain in the region 8 where the alignment mark is formed.

In the above-described embodiments, the barrier film 20d remain in the region 8 where the alignment mark to be formed, but the barrier film 20d may not remain in the region 8 where the alignment mark to be formed.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A method for manufacturing a semiconductor device including a capacitance element having a lower electrode, a dielectric film formed over the lower electrode and an upper electrode formed over the dielectric film, said method comprising:
forming an insulation layer over a semiconductor substrate;
burying a first conduction layer containing Cu in the insulation layer in a first region and burying an interconnection containing Cu in the insulation layer in a second region;
forming a barrier film of a conductive material over the first conduction layer, the interconnections and the insulation layer;
forming a dielectric film over the barrier metal film;
forming a second conduction layer over the dielectric film;
patterning the second conduction layer to form an upper electrode formed of the second conduction layer in the first region; and
patterning the dielectric film and the barrier metal film to cover an upper surface of the first conduction layer by the first barrier film formed of the barrier metal film, form a lower electrode including the first conduction layer and the first barrier film, and covering an upper surface of the interconnection by the second barrier film formed of the barrier metal film.

2. The method for manufacturing the semiconductor device according to claim 1, wherein
the burying the first conduction layer and the interconnection includes forming a first trench in the insulation layer in the first region, enclosing a part of the insulation layer and forming linearly a second trench in the insulation layer in the second region, and burying the first conduction layer in the first trench and burying the interconnection in the second trench.

3. The method for manufacturing the semiconductor device according to claim 1, further comprising after the forming the barrier metal film and before the forming the dielectric film,
polishing a surface of the barrier metal film to planarize the surface of the barrier metal film.

4. The method for manufacturing the semiconductor device according to claim 1, wherein
the barrier metal film contains Ta, TaN or TiN.

5. The method for manufacturing the semiconductor device according to claim 1, in which
in the burying the first conduction layer and the interconnection, a third conduction layer containing Cu is further buried in the insulation layer in a third region, and
said method further comprises after the burying the first conduction layer and the interconnection and before the forming the barrier metal film,
etching an upper part of the insulation layer in the third region to expose an upper part of the third conduction layer beyond the insulation layer to form an alignment mark of the third conduction layer.

6. The method for manufacturing the semiconductor device according to claim 1, wherein
in patterning the barrier metal film, a resistance layer of the barrier metal film is further formed.
